(19) United States
(12) Patent Application Publication
(10) Pub. No.: US 2008/0230907 A1
(43) Pub. Date: Sep. 25, 2008

(54) INTEGRATED CIRCUIT SYSTEM WITH CARBON ENHANCEMENT

(75) Inventors: Wuping Liu, Singapore (SG); Kevin S. Petrarca, Newburgh, NY (US); Johnny Widodo, Singapore (SG); Lawrence A. Clevenger, LaGrangeville, NY (US); Wai-Kin Li, Beacon, NY (US)

Correspondence Address: LAW OFFICES OF MIKIO ISHIMARU, 333 W. EL CAMINO REAL, SUITE 330, SUNNYVALE, CA, 94087, US

(73) Assignees: CHARTERED SEMICONDUCTOR MANUFACTURING LTD., Singapore (SG); INTERNATIONAL BUSINESS MACHINES CORPORATION, Armonk, NY (US)

(21) Appl. No.: 11/690,080

(22) Filed: Mar. 22, 2007

(51) Int. Cl. H01L 23/48

(52) U.S. Cl. 257/751; 257/E23.01

(57) ABSTRACT

An integrated circuit hard mask processing system is provided including providing a substrate having an integrated circuit; forming an interconnect layer over the integrated circuit; applying a low-K dielectric layer over the interconnect layer; forming a via opening through the low-K dielectric layer to the interconnect layer; and forming a carbon implant region around the via opening, a trench opening, or a combination thereof, for protecting the low-K dielectric layer.

### TECHNICAL FIELD

The present invention relates generally to the fabrication of semiconductor integrated circuit devices, and more particularly to the formation integrated circuit devices with low-K inter-level dielectric (ILD).

### BACKGROUND ART

Modern consumer electronics, such as cellular phones, digital cameras, and music players, are packing more integrated circuits into an ever shrinking physical space with the expectations for decreasing cost. Numerous technologies have been developed to meet these requirements. One cornerstone for consumer electronics to continue proliferation into everyday life is the on-going size reduction of the integrated circuits.

In the field of semiconductor fabrication, the use of dielectric materials having a low dielectric constant (k<2.5), known as low-K materials, is well known. Low-K dielectrics are used primarily in backend processing. Backend processing refers generally to processing subsequent to the formation of transistors in the wafer substrate to interconnect the transistors, typically with multiple levels of metal interconnect. Use of hard mask plays an important role in certain low-k integration schemes. The hard mask serves as a sacrificial layer atop of the low-k which avoid direct contact between low-k and photoresist to prevent resist poisoning, ensure low-k film withstands harsh resist rework conditions, and facilitate copper (Cu) chemical-mechanical polishing (CMP) for uniform processing control. Each interconnect level is separated by an inter-level dielectric (ILD). The individual interconnects within a single interconnect level are also separated by a dielectric material that may or may not be the same as the ILD. Vias or contacts are formed in the ILD and filled with conductive material to connect the interconnect levels in a specified pattern to achieve a desired functionality.

Various low-K materials have been used in low-K backend processing with mixed results. Integration of low-K material into existing fabrication processes is particularly challenging in the case of backend processing that includes the use of CMP. CMP is a technique by which each interconnect level is formed in many existing processes. In a CMP process, as implied by its name, a film or layer is physically polished with a rotating polishing pad in the presence of a “slurry” that contains mechanical abrasion components and/or chemical components to produce a smooth upper surface and to remove excess conductive material and thereby isolate the individual interconnects from one another.

One of the key patterning issues related to hard mask integration schemes is its overhang (or low-k undercut) after pattern transfer. The hard mask overhang is defined as the protruding part of hard mask at the trench top opening above the low-k dielectric. Formation of hard mask is primarily related to post-trench-etch resist ash. During that step, the low-k surface at the trench sidewall is modified, and an oxide-like layer is formed. Compared to hard mask or low-k film, this oxide-like layer is less resistant to the following wet etch cleaning step (usually a mild aqueous solution containing weak acidic buffer solutions). After wet etch cleaning, an overhang in the trench profile is formed by the removal of the oxide-like layer. A slower hard mask etch rate as compared to low-k film, also accounts for hard mask overhang.

It is well known that low k materials are susceptible to side wall damage during reactive ion etch (RIE). This damage is apparent after a post RIE wet clean, and results in a carbon depleted area that is etched in the wet clean process. This causes an undercut with respect to the hard mask. The damaged portion of the material on the sidewall is not left in place because it is of a high k value and would be detrimental to the efficiency of the semiconductor product. However, the removal of this damaged area gives rise to another type of problem, the hard mask is left in place and the damaged material below is removed creating the overhang of the hard mask material. This type of reentrant profile is extremely difficult to process through the liner/seed and metal fill sectors.

The overhang profile may degrade coverage of the copper liner process, and may leave copper voids under the overhang area. Exposed voids after copper CMP, form localized slit defects, may cause both yield loss and reliability degradation.

Thus, a need still remains for an integrated circuit system that integrates a low-K dielectric with a hard mask process that does not produce the slit defects, which may adversely impact yield and reliability. In view of the demand for smaller integrated circuit geometries and the increasing operational frequencies of the end devices, it is increasingly critical that answers be found to these problems. Solutions to these problems have been long sought but prior developments have not taught or suggested any solutions and, thus, solutions to these problems have long eluded those skilled in the art.

### DISCLOSURE OF THE INVENTION

The present invention provides an integrated circuit hard mask processing system including providing a substrate having an integrated circuit; forming an interconnect layer over the integrated circuit; applying a low-K dielectric layer over the interconnect layer; forming a via opening through the low-K dielectric layer to the interconnect layer; and forming a carbon implant region around the via opening, a trench opening, or a combination thereof, for protecting the low-K dielectric layer.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a partial cross-sectional view of an integrated circuit system with carbon enhancement, in an embodiment of the present invention;

FIG. 2 is a partial cross-sectional view of the integrated circuit system, in an interconnect defining phase of manufacturing;

FIG. 3 is a partial cross-sectional view of the integrated circuit system, in a reactive ion etch phase of manufacturing;

FIG. 4 is a partial cross-sectional view of the integrated circuit system, in a carbon implant phase of manufacturing;

FIG. 5 is a partial cross-sectional view of the integrated circuit system, in an etch and cap layer opening phase of manufacturing; and

FIG. 6 is a flow chart of an integrated circuit system, for manufacturing the integrated circuit system, in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known process steps are not disclosed in detail. Likewise, the drawings showing embodiments of the apparatus are semi-diagrammatic and not to scale and, particularly, some of the dimensions are for the clarity of presentation and are shown greatly exaggerated in the drawing FIGs. In addition, where multiple embodiments are disclosed and described having some features in common, for clarity and ease of illustration, description, and comprehension thereof, similar and like features one to another will ordinarily be described with like reference numerals.

For expository purposes, the term “horizontal” as used herein is defined as a plane parallel to the conventional plane or surface of the wafer substrate regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements. The term “processing” as used herein includes deposition of material or photoresist, patterning, exposure, development, etching, cleaning, and/or removal of the material or photoresist as required in forming a described structure.

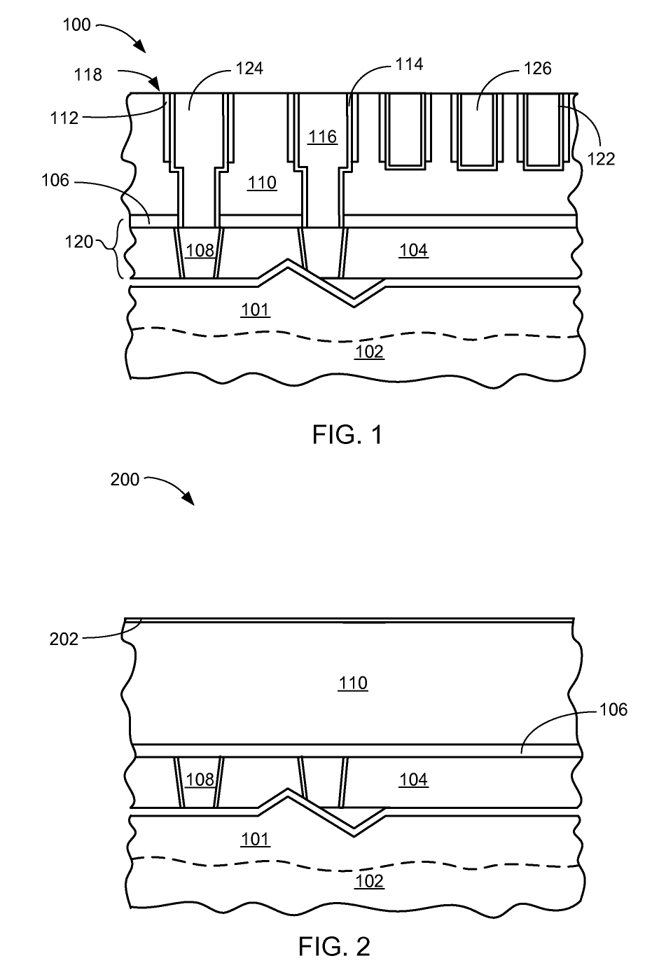

Referring now to FIG. 1, therein is shown a partial cross-sectional view of an integrated circuit system 100 with carbon enhancement, in an embodiment of the present invention. The partial view depicts a substrate 102, having an integrated circuit 101 fabricated thereon, an inter-level dielectric layer 104 is deposited over the integrated circuit 101 and is covered by a cap layer 106, such as silicon nitride (SiN), carbon-doped Silicon nitride, or nitrogen-doped silicon carbid (nBlok). An interconnect 108, such as a copper interconnect, is electrically connected to the integrated circuit 101 through a contact layer (not shown).

A low-K dielectric layer 110 is deposited over the inter-level dielectric layer 104 and the cap layer 106. The inter-level dielectric layer 104 and the low-K dielectric layer 110 are substantially similar in the chemical make-up and dielectric value (K).

The dielectric layers may have dielectric constants from 4.2 to 3.9 and are of materials such as silicon oxide (SiOₓ), tetraethylorthosilicate (TEOS), borophosphosilicate (BPSG) glass, etc. The low-K dielectric layers may have lower dielectric constants from 3.9 to 2.5 and are of materials such as fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), etc. The ultra-low dielectric layers may have ultra-low dielectric constants below 2.5 and are of such materials as polytetrafluoroethylene (PTFE) commercially available as Teflon-AF and Teflon microemulsion, polyimide nanofoams such as polypropylene oxide, silica aerogels, silica xerogels, and mesoporous silica.

A carbon implant region 112 surrounds a diffusion barrier layer 114, such as a seed metal layer which is deposited over the low-K dielectric layer 110, and inside the patterned interconnects. The diffusion barrier layer 114 may include an initial 50-200 Å layer of titanium (Ti), tantalum (Ta) or tantalum nitride (TaN), used as a diffusion barrier, that is covered by a 300-2000 Å layer of copper (Cu). An interconnect metal 116, such as copper, is deposited on the diffusion barrier layer 114. A structure surface 118 is formed by a chemical-mechanical polish establishing a coplanar surface between the interconnect metal 116 and the low-K dielectric layer 110. An interconnect layer 120 is comprised of the inter-level dielectric layer 104 and the cap layer 106.

In the present invention, the presence of residual thickness of the carbon implant region 112, or the mechanically and/or chemically softer type of the low-K dielectric layer 110, or the mechanically and/or chemically softer type of the inter-level dielectric layer 104, does not degrade the high frequency operation of the integrated circuit 101.

During the reactive ion etch process that is used to produce a trench 126, the thickness of the carbon implant region 112 is reduced. The residual of the carbon implant region 112 present on the low-K dielectric layer 110 acts as a protection from the reactive ion etch and the post etch wet cleaning process used to pattern the next level of interconnect. The protection of the low-K dielectric layer 110 allows the forming of a vertical sidewall 122 on a via 124, the trench 126, or a combination thereof.

Referring now to FIG. 2, therein is shown a partial cross-sectional view of an integrated circuit system 200, in a hard mask deposition phase of manufacturing. The partial cross-sectional view depicts the substrate 102, having the integrated circuit 101 fabricated thereon, the inter-level dielectric layer 104 is deposited over the integrated circuit 101 and is covered by the cap layer 106, such as silicon nitride (SiN), carbon-doped Silicon nitride, or nitrogen-doped silicon carbid (nBlok). The interconnect 108, such as a copper interconnect, is electrically connected to the integrated circuit 101 through a contact layer (not shown).

The low-K dielectric layer 110 is deposited over the inter-level dielectric layer 104 and the cap layer 106. The inter-level dielectric layer 104 and the low-K dielectric layer 110 are substantially similar in the chemical make-up and dielectric value (K). A hard mask layer 202, such as silicon oxide (SiOₓ) or the high K dielectric layer having a dielectric (K) value of greater than 3.7, or the mechanically and/or chemically harder type of the low-K dielectric layer 110, is deposited over the low-K dielectric layer 110. The hard mask layer 202 isolates the low-K dielectric layer 110 for further processing.

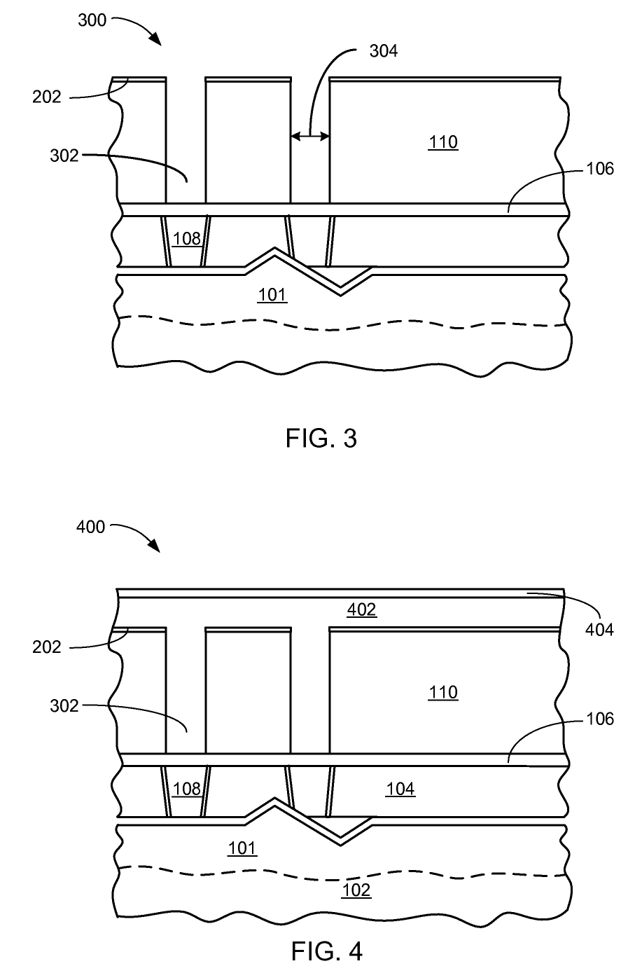

Referring now to FIG. 3, therein is shown a partial cross-sectional view of an integrated circuit system 300, in a via formation phase of manufacturing. The partial cross-sectional view depicts a via opening 302 formed through the hard mask layer 202 and the low-K dielectric layer 110. The via opening 302 is aligned with the interconnect 108, but does not penetrate the cap layer 106. The positioning of the via opening 302 is critical to the function of the integrated circuit 101. The via opening 302 is formed by an etch process that cuts through the hard mask layer 202 and the low-K dielectric layer 110. This etch process produces an initial diameter opening 304 for the next level of processing.

Referring now to FIG. 4, therein is shown a partial cross-sectional view of an integrated circuit system 400, in a via fill phase of manufacturing. The partial cross-sectional view depicts the via opening 302 filled with a planarization polymer 402. The planarization polymer 402 is spun over the hard mask layer 202. A low temperature oxide 404 is formed over the planarization polymer 402. The low temperature oxide 404 and the planarization polymer 402 are sacrificial layers that will be removed later in the process.

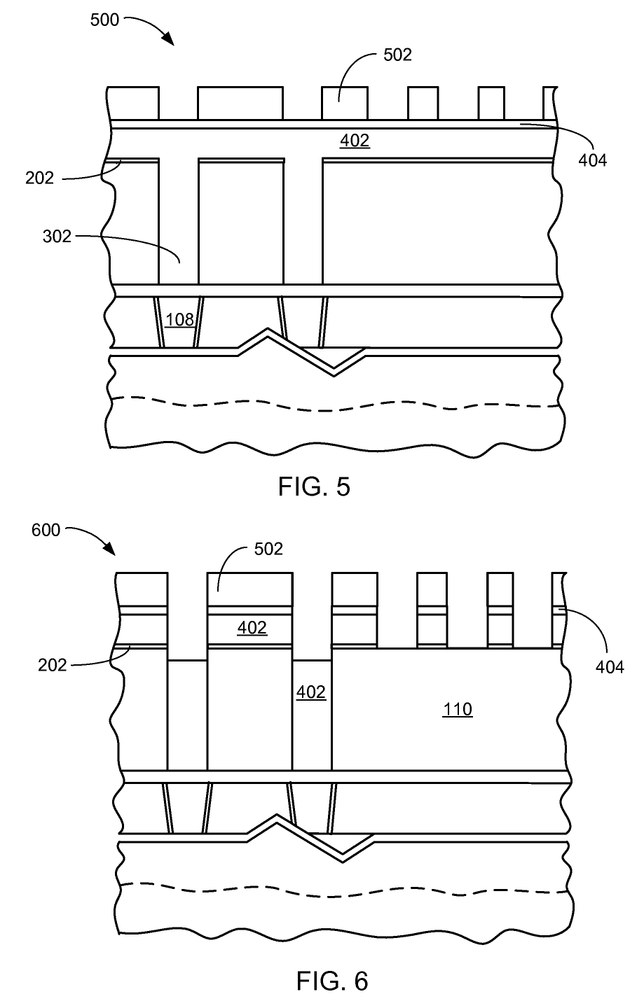

Referring now to FIG. 5, therein is shown a partial cross-sectional view of an integrated circuit system 500, in a photoresist patterning phase of manufacturing. The partial cross-sectional view depicts a photoresist 502 patterned over the low temperature oxide 404 and the planarization polymer 402. This step of manufacturing is critical to the integrity of the final product. The pattern of the photoresist 502 defines the path of the electrical interconnects (not shown) on this interconnect level. The relative position of the openings in the photoresist 502 to the via opening 302 and the interconnect 108 is another critical dimension.

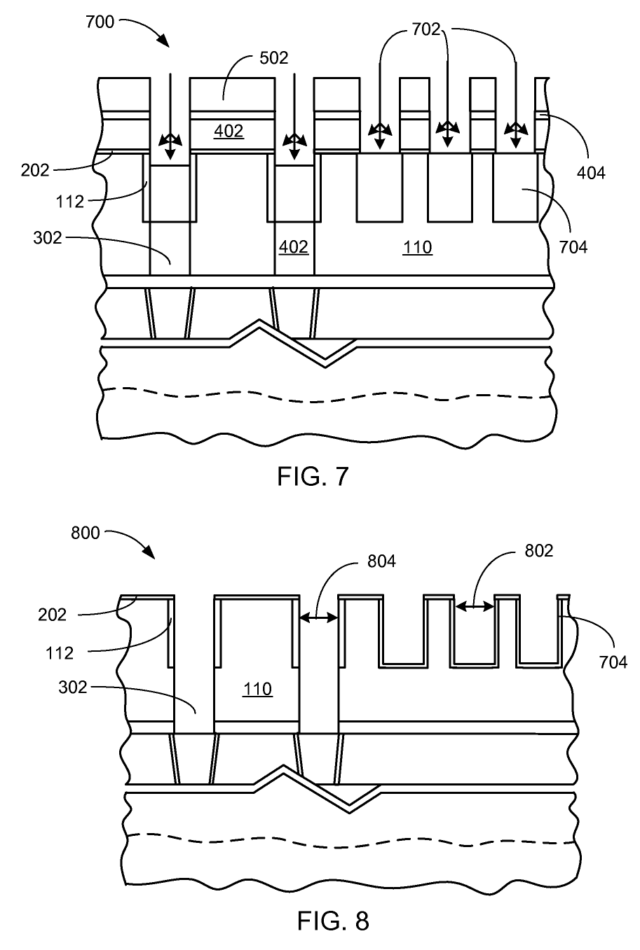

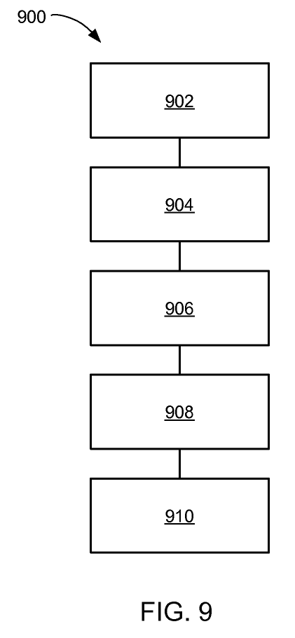

Referring now to FIG. 6, therein is shown a partial cross-sectional view of an integrated circuit system 600, in a hard mask opening phase of manufacturing. The partial cross-sectional view depicts the low temperature oxide 404, the planarization polymer 402, and the hard mask layer 202, having been opened by a standard etch process. The etch solution cuts through the low temperature oxide 404, the planarization polymer 402, and the hard mask layer 202. In the via opening 302, the planarization polymer 402 is removed below the level of the hard mask layer 202. The hard mask layer 202, that is newly etched, exposes the low-K dielectric layer 110 for further processing. The photoresist 502 remains over the low temperature oxide 404.

Referring now to FIG. 7, therein is shown a partial cross-sectional view of an integrated circuit system 700, in a carbon implant 702 phase of manufacturing. The partial cross-sectional view depicts the carbon implant region 112 around the via opening 302 and a trench implant region 704. A non-orthogonal version of the carbon implant 702 is deposited around the via opening 302 to insure that the future side walls, of etched regions for metal structures, will have sufficient carbon content in the carbon implant region 112 to protect the low-K dielectric layer 110 from the reactive ion etch and the post etch wet cleaning process. A sufficient concentration of the carbon implant 702 is maintained in the carbon implant region 112 for balancing the carbon depletion caused by the reactive ion etch and the post etch wet cleaning process. The goal of the balancing is to leave the low-K dielectric layer 110 with the same concentration of carbon that it had prior to the carbon implant 702. As a result the vertical sidewall 122 in the via opening 302 of the low-K dielectric layer 110 has a similar concentration of carbon as the low-K dielectric layer 110 in other areas. The addition of the carbon implant region 112 prevents the low-K dielectric layer 110 from being undercut below the hard mask layer 202.

Referring now to FIG. 8, therein is shown a partial cross-sectional view of an integrated circuit system 800, in post etch and cleaning phase of manufacturing. The partial cross-sectional view depicts the trench implant region 704 around a trench opening 802 that has been etched into the low-K dielectric layer 110 by a reactive ion etch and wet cleaning process. The etched diameter opening 804 of the via opening 302 may be wider than the initial diameter opening 304, of FIG. 3. The enriched carbon in the carbon implant region 112 and the trench implant region 704 allow the low-K dielectric layer 110 to etch at a substantially similar rate as the hard mask layer 202.

The carbon implant region 112 and the trench implant region 704 are areas of carbon enrichment that will have the carbon depleted during the reactive ion etch and post etch wet cleaning process. The carbon implant region 112, around the via opening 302, and the trench implant region 704, around the trench opening 802, prevent the undercut of the low-K dielectric layer 110, which is the prevalent manufacturing difficulty with the hard mask layer 202 in a dual damascene copper interconnect process.

Referring now to FIG. 9, therein is shown a flow chart of an integrated circuit system 900 for manufacturing the integrated circuit system 100 in an embodiment of the present invention. The system 900 includes providing a substrate having an integrated circuit in a block 902; forming an interconnect layer over the integrated circuit in a block 904; applying a low-K dielectric layer over the interconnect layer in a block 906; forming a via opening through the low-K dielectric layer to the interconnect layer in a block 908; and forming a carbon implant region around the via opening, a trench opening, or a combination thereof, for protecting the low-K dielectric layer in a block 910.

In greater detail, a system to manufacture an integrated circuit system, according to an embodiment of the present invention, is performed as follows:
1. Providing a substrate having an integrated circuit. (FIG. 1)
2. Forming an interconnect layer over the integrated circuit including providing an interconnect within the interconnect layer. (FIG. 1)

3. Applying a low-K dielectric layer over the interconnect layer. (FIG. 1)

4. Applying a hard mask layer over the low-K dielectric layer includes protecting the low-K dielectric layer from the photoresist. (FIG. 1)

5. Forming a via opening through the hard mask layer and the low-K dielectric layer to the interconnect layer includes forming an opening in a cap layer. (FIG. 1)

6. Forming a carbon implant around the via opening for protecting the low-K dielectric layer from a reactive ion etch and a post etch wet cleaning process including preventing an undercut below the hard mask layer. (FIG. 4)

7. Depositing interconnect metal in the via opening to form a connection to the interconnect within the interconnect layer. (FIG. 1) and

8. Chemical-mechanical polishing the interconnect metal and the low-K dielectric layer. (FIG. 1)

It has been discovered that the present invention provides a solution to the most prevalent manufacturing problem in the dual damascene process. By supplying additional carbon in the low-K dielectric layer, low-K dielectric layer etches at substantially the same rate as the hard mask layer.

It has been discovered that the present invention thus has numerous aspects.

A principle aspect that has been unexpectedly discovered is that the present invention provides a cost effective solution for the management of the overhang of the hard mask layer created during the reactive ion etch and post etch wet cleaning processes of manufacture.

Another aspect is that the amount of carbon implant may be controlled to substantially balance the reactive ion etch and post etch wet cleaning processes. The benefit of the balance of the carbon content in the low-K dielectric layer is that it prevents the undercut of the low-K dielectric layer relative to the hard mask layer for the interconnect level.

Yet another important aspect of the present invention is that it valuably supports and services the historical trend of reducing costs, simplifying systems, and increasing performance.

These and other valuable aspects of the present invention consequently further the state of the technology to at least the next level.

Thus, it has been discovered that the integrated circuit system with carbon enhancement of the present invention furnishes important and heretofore unknown and unavailable solutions, capabilities, and functional aspects for integrating hard mask layer into the dual damascene low-K dielectric manufacturing process. The resulting processes and configurations are straightforward, cost-effective, uncomplicated, highly versatile and effective, can be surprisingly and unobviously implemented by adapting known technologies, and are thus readily suited for efficiently and economically manufacturing integrated circuit devices low-K dielectric interconnect structures fully compatible with conventional manufacturing processes and technologies.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

1. An integrated circuit system comprising:
providing a substrate having an integrated circuit;
forming an interconnect layer over the integrated circuit;
applying a low-K dielectric layer over the interconnect layer, the low-K dielectric layer having a first concentration of carbon:
forming a via opening through the low-K dielectric layer to the interconnect layer; and
forming a carbon implant region around the via opening, a trench opening, or a combination thereof, for protecting the low-K dielectric layer, the carbon inplant region enriched to have a second concentration of carbon greater than the first concentration of carbon.

2. The system as claimed in claim 1 further comprising providing a diffusion barrier layer between the low-K dielectric layer and the interconnect metal.

3. The system as claimed in claim 1 wherein protecting the low-K dielectric layer includes depleting a carbon implant during a reactive ion etch and post etch wet cleaning process.

4. The system as claimed in claim 1 further comprising providing a cap layer between the low-K dielectric layer and the interconnect layer.

5. The system as claimed in claim 1 wherein forming a carbon implant region includes depositing a sufficient amount of the carbon implant for balancing the carbon concentration of the low-K dielectric layer.

6. An integrated circuit system comprising:
providing a substrate having an integrated circuit;
forming an interconnect layer over the integrated circuit including providing an interconnect within the interconnect layer;
applying a low-K dielectric layer over the interconnect layer, the low-K dielectric layer having a first concentration of carbon;
applying a hard mask layer over the low-K dielectric layer includes protecting the low-K dielectric layer from a photoresist;
forming a via opening through the hard mask layer and the low-K dielectric layer to the interconnect layer includes forming an opening in a cap layer;
forming a carbon implant region around the via opening for protecting the low-K dielectric layer including preventing an undercut below the hard mask layer, the carbon implant region enriched to have a second concentration of carbon greater than the first concentration of carbon;
depositing interconnect metal in the via opening to form a connection to the interconnect within the interconnect layer; and
chemical-mechanical polishing the interconnect metal and the low-K dielectric layer.

7. The system as claimed in claim 6 further comprising providing a diffusion barrier layer between the low-K dielectric layer and the interconnect metal in which the diffusion barrier layer forms a barrier to the interconnect metal.

8. The system as claimed in claim 6 wherein protecting the low-K dielectric layer includes depleting a carbon implant during a reactive ion etch and post etch wet cleaning process for forming a vertical sidewall in a via, a trench, or a combination thereof.

9. The system as claimed in claim 6 further comprising providing a cap layer between the low-K dielectric layer and the interconnect layer in which the cap layer is silicon nitride.

10. The system as claimed in claim 6 wherein forming the carbon implant region includes depositing a sufficient concentration of a carbon implant to balance the carbon content of the low-K dielectric layer for forming a vertical sidewall in a via, a trench, or a combination thereof.

11. An integrated circuit system comprising:
a substrate having an integrated circuit;
an interconnect layer over the integrated circuit;
a low-K dielectric layer applied over the interconnect layer, the low-K dielectric layer having a first concentration of carbon;
a via opening formed by the low-K dielectric layer having a first opening, aligned with the interconnect layer having a second opening;
a carbon implant region around the via opening in the low-K dielectric layer, the carbon implant region enriched to have a second concentration of carbon greater than the first concentration of carbon; and
an interconnect metal deposited in the via opening, includes the interconnect metal isolated from the low-K dielectric layer.

12. The system as claimed in claim 11 further comprising a diffusion barrier layer between the low-K dielectric layer and the interconnect metal.

13. The system as claimed in claim 11 wherein the interconnect metal is polished to be coplanar with the low-K dielectric layer.

14. The system as claimed in claim 11 further comprising a cap layer between the low-K dielectric layer and the interconnect layer.

15. The system as claimed in claim 11 further comprising a vertical sidewall in the via opening of the low-K dielectric layer having a similar concentration of carbon as the low-K dielectric layer in other areas.

16. The system as claimed in claim 11 further comprises:
an interconnect within the interconnect layer;
a cap layer having an opening; and
a connection between the interconnect metal and the interconnect within the interconnect layer.

17. The system as claimed in claim 16 further comprising a diffusion barrier layer between the low-K dielectric layer and the interconnect metal wherein the diffusion barrier layer forms a barrier to the interconnect metal.

18. The system as claimed in claim 16 wherein the interconnect metal is coplanar with the low-K dielectric layer and the diffusion barrier layer.

19. The system as claimed in claim 16 further comprising a cap layer between the low-K dielectric layer and the interconnect layer wherein the cap layer includes silicon nitride.

20. The system as claimed in claim 16 further comprising a vertical sidewall in a via within the low-K dielectric layer includes a vertical sidewall in a trench, or a combination thereof.

21. An integrated circuit system comprising:
providing a substrate having an integrated circuit;
forming an interconnect layer over the integrated circuit;
applying a low-K dielectric layer over the interconnect layer, the low-K dielectric layer having a first concentration of carbon;
applying a hard mask layer over the low-K dielectric layer;
forming a via opening through the hard mask layer and the low-K dielectric layer to the interconnect layer;
filling the via opening with a planarization material;
forming a low temperature oxide over the planarization material; patterning a photoresist over the low temperture oxide;
etching the low temperature oxide, the planarization material, the hard mask layer, and a portion of the low-K dielectric layer to form a via opening, and etching the low temperature oxide and the planarization material to form a trench opening;
implanting carbon to enrich the carbon in the via opening and the trench opening, the carbon implant region enriched to have a second concentration of carbon greater than the first concentration of carbon;
etching the via opening and the hard mask layer at substantially the same rate, the etching removing the photoresist, the low temperature oxide, a portion of the hard mask layer, and a portion of the planarization material; and
reactive ion etching and wet cleaning to remove the planarization material and form a trench.

22. The system as claimed in claim 21 wherein the filling the via opening with a planarization material includes using a polymer.

23. The system as claimed in claim 21 wherein the reactive ion etching and wet cleaning leaves the via opening and the trench surrounded by an enriched carbon implant having a concentration of carbon greater than the concentration of carbon in the low-K dielectric layer.
